(19) United States
(12) Patent Application Publication
(10) Pub. No.: US 2025/0233355 A1
(43) Pub. Date: Jul. 17, 2025

(54) COOLING DEVICE

(71) Applicant: ASUSTEK COMPUTER INC., TAIPEI (TW)

(72) Inventors: Jui-Cheng CHIEN, TAIPEI (TW); Po-Hsun CHEN, TAIPEI (TW)

(21) Appl. No.: 18/641,695

(22) Filed: Apr. 22, 2024

(30) Foreign Application Priority Data
Jan. 11, 2024 (TW) 113101239

(51) Int. Cl. H01R 13/62

(52) U.S. Cl. CPC H01R 13/62

(57) ABSTRACT

The disclosure provides a cooling device, including a plurality of cooling fans. Each cooling fan includes a frame and a first fastener. The frame includes a first side surface, a second side surface, and a third surface. The first side surface includes a first groove extending to a junction of the first side surface and the third side surface. A first fastening slot is provided at a position of the third side surface close to the second side surface. The first fastener includes a first pivoting portion and a first buckling portion. The first pivoting portion is arranged in the first groove and pivotally connected to the frame. The first side surface is adapted to abut against the second side surface of another cooling fan. The first buckling portion is adapted to selectively cover the first groove or be buckled to the first fastening slot of the another cooling fan.

### CROSS-REFERENCE TO RELATED APPLICATION

This application claims the priority benefit of Taiwan Application Serial No. 113101239, filed on Jan. 11, 2024. The entirety of the above-mentioned patent application is hereby incorporated by reference herein and made a part of specification.

### BACKGROUND OF THE INVENTION

### Field of the Invention

The disclosure relates to a cooling device, and in particular, to a cooling device including a plurality of cooling fans.

### Description of the Related Art

Computer hosts or servers generate a large amount of heat during operation, and a plurality of cooling fans generally needs to be installed for these electronic devices to improve the cooling efficiency.

However, each cooling fan includes its own connecting wire. Using the plurality of cooling fans easily leads to complex internal wires in a chassis, making it difficult to manage the wires and install the cooling fans.

### BRIEF SUMMARY OF THE INVENTION

The disclosure provides a cooling device, including a plurality of cooling fans. Each cooling fan includes a frame and a first fastener. The frame includes a first side surface, a second side surface, and a third side surface. The second side surface is opposite to the first side surface, and the third side surface is adjacent to the first side surface and the second side surface. The first side surface includes a first groove, the first groove extends to a junction of the first side surface and the third side surface, and a first fastening slot is provided at a position of the third side surface that is close to the second side surface. The first fastener includes a first pivoting portion and a first buckling portion. The first pivoting portion is arranged in the first groove and pivotally connected to the frame, and the first buckling portion is connected to the first pivoting portion. The first side surface is adapted to abut against the second side surface of another cooling fan to be connected, and the first buckling portion is adapted to selectively cover the first groove or be buckled to the first fastening slot of the another cooling fan to be connected.

In the disclosure, the cooling device includes the plurality of cooling fans. The plurality of cooling fans is connected in rows by fastening and connection between the first fasteners and the first fastening slots. This helps simplify an installation procedure of the cooling fans. In addition, when the first fastener does not need to be connected to a cooling fan, the first fastener may be used to cover the first groove, to prevent a fastening structure and an electrical contact of the first fastener from being exposed, helping improve the product safety.

### BRIEF DESCRIPTION OF THE DRAWINGS

FIG. 1 is a schematic diagram of a cooling device according to an embodiment of the disclosure;

FIG. 2 is a three-dimensional schematic diagram of the cooling device in FIG. 1 from another perspective;

FIG. 3 is a three-dimensional schematic diagram of a cooling fan according to an embodiment of the disclosure;

FIG. 4 is a three-dimensional schematic diagram of the cooling fan in FIG. 3 from another perspective;

FIG. 5 is a three-dimensional schematic diagram of the cooling fan in FIG. 3 in an accommodated mode;

FIG. 6 is a partial schematic perspective view of an internal structure corresponding to a position of a first groove in FIG. 3;

FIG. 7 is a partial schematic perspective view of an internal structure corresponding to a position of a first groove in FIG. 5; and

FIG. 8 is a three-dimensional schematic diagram of a transfer element according to an embodiment of the disclosure.

### DETAILED DESCRIPTION OF THE EMBODIMENTS

The following describes specific embodiments of the disclosure in more details with reference to the schematic diagrams. Based on the following description and a patent scope of the disclosure, advantages and features of the disclosure will be clearer. It is to be noted that, the accompanying drawings are in simplified forms and are not drawn to an accurate scale, and are only used for assisting in understanding the embodiments of the disclosure conveniently and clearly.

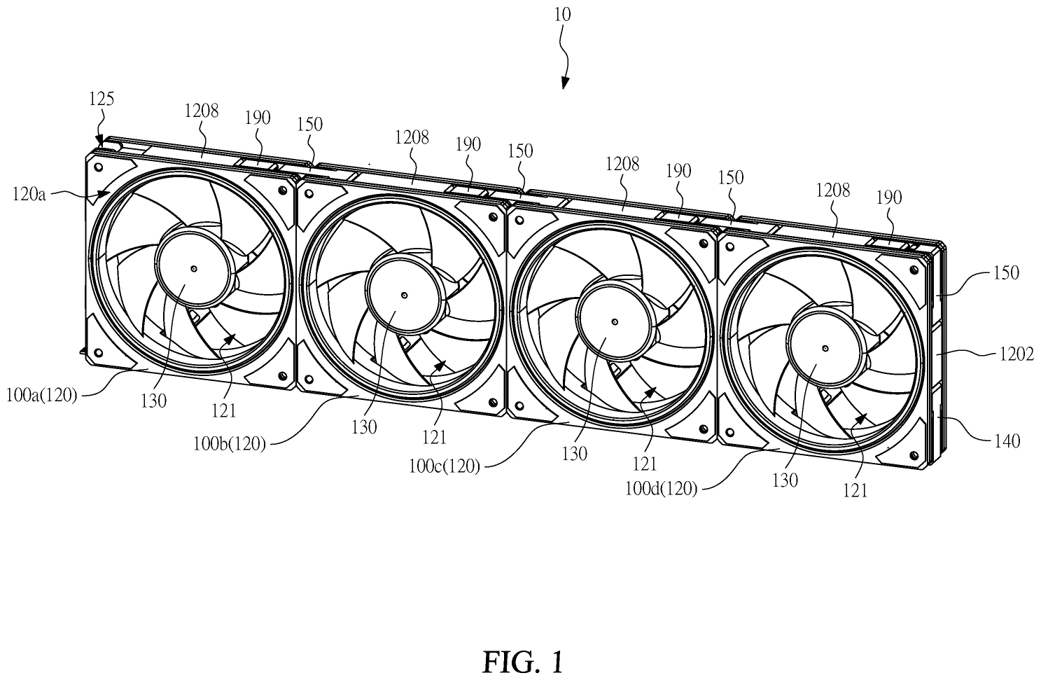

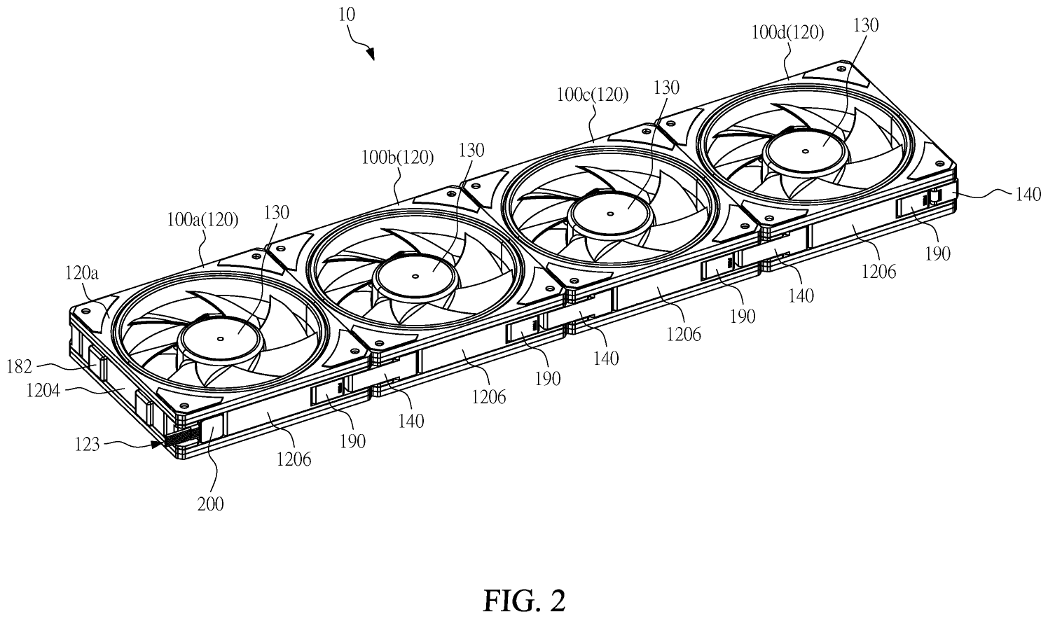

FIG. 1 is a three-dimensional schematic diagram of a cooling device 10 according to an embodiment of the disclosure. FIG. 2 is a three-dimensional schematic diagram of the cooling device 10 in FIG. 1 from another perspective.

As shown in the figures, the cooling device 10 includes a plurality of cooling fans 100a, 100b, 100c, and 100d with a same structure that are connected in rows, and obtains electricity and a control signal through a transfer element 200.

The four cooling fans 100a, 100b, 100c, and 100d shown in the figures are connected in rows. The transfer element 200 is electrically connected to the foremost cooling fan 100a, to input the electricity and the control signal. Based on an actual requirement, the cooling device 10 alternatively includes two or three cooling fans, or is connected to more cooling fans.

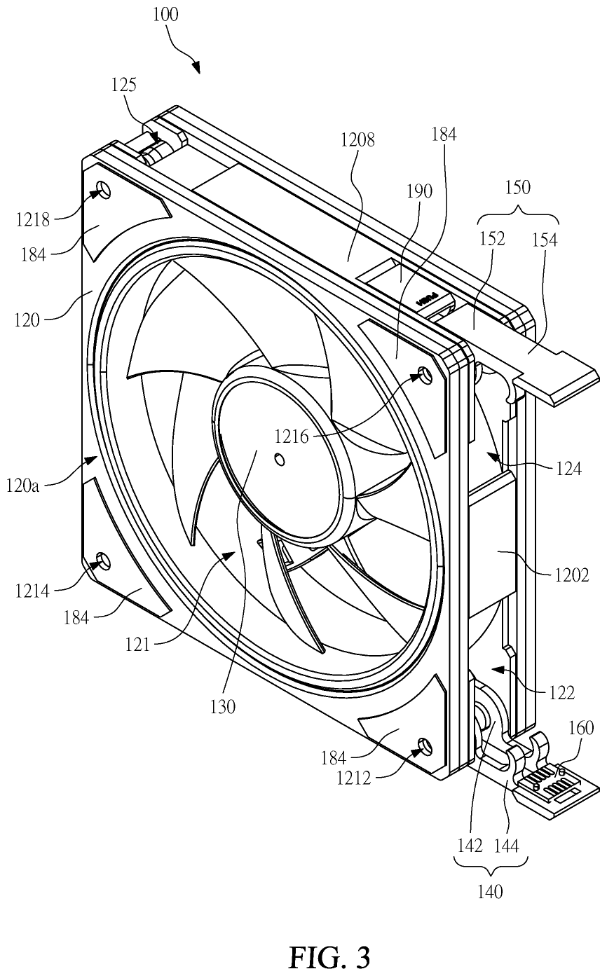

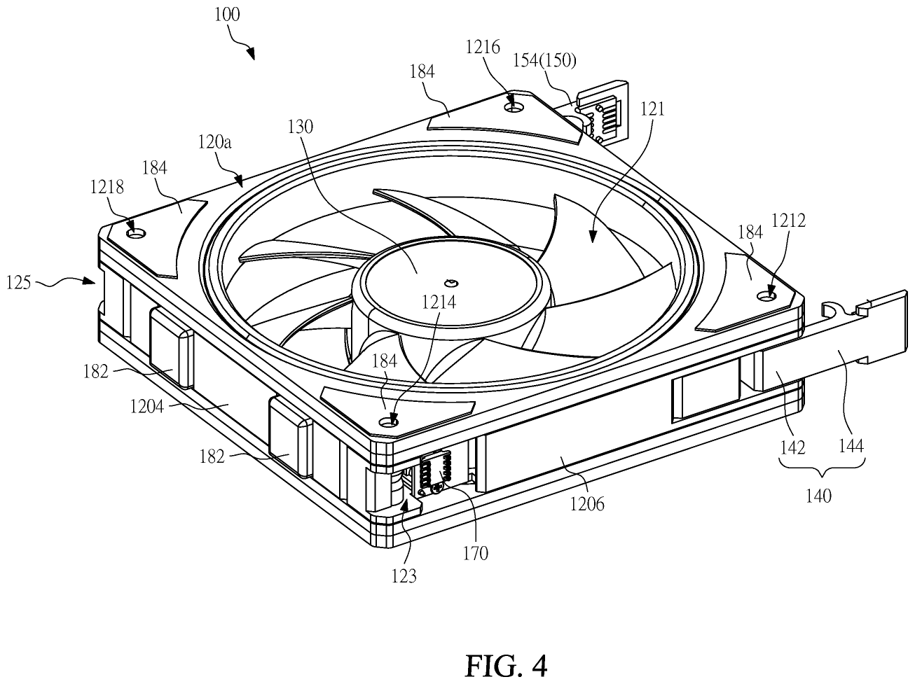

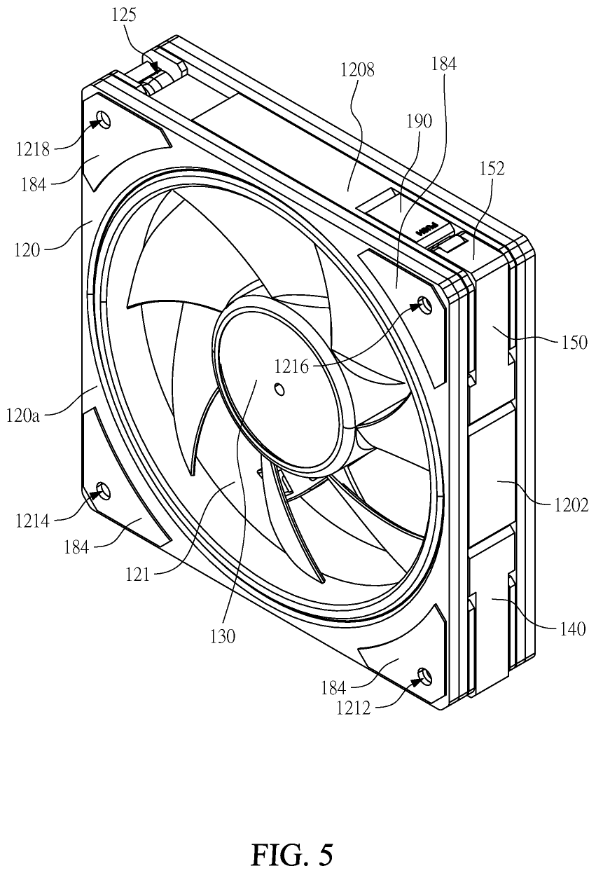

Referring to FIG. 3 to FIG. 5 together, FIG. 3 is a three-dimensional schematic diagram of a cooling fan 100 according to an embodiment of the disclosure. FIG. 4 is a three-dimensional schematic diagram of the cooling fan 100 in FIG. 3 from another perspective. FIG. 5 is a three-dimensional schematic diagram of the cooling fan 100 in FIG. 3 in an accommodated mode. The cooling fan 100 is applicable to the cooling device 10 in FIG. 1.

As shown in the figures, the cooling fan 100 includes a frame 120, a fan blade module 130, a first fastener 140, and a second fastener 150.

The frame 120 is roughly square in shape and includes a central opening 121. The fan blade module 130 is arranged inside the central hole 121. The cooling fan 100 is an axial fan, and the fan blade module 130 rotates to drive an airflow to flow along the central opening 121.

The frame 120 includes a first side surface 1202, a second side surface 1204, a third side surface 1206, and a fourth side surface 1208. The second side surface 1204 is opposite to the first side surface 1202, the third side surface 1206 is adjacent to the first side surface 1202 and the second side surface 1204, and the fourth side surface 1208 is opposite to the third side surface 1206 and is adjacent to the first side surface 1202 and the second side surface 1204.

A first groove 122 is provided on a side of the first side surface 1202 that is close to the third side surface 1206, and the first groove 122 extends to a junction of the first side surface 1202 and the third side surface 1206. A first fastening slot 123 is provided at a position of the third side surface 1206 that is close to the second side surface 1204.

The first fastener 140 includes a first pivoting portion 142 and a first buckling portion 144. The first pivoting portion 142 is arranged in the first concave 122 and pivotally connected to the frame 120. The first buckling portion 144 is connected to the first pivoting portion 142 to be integrally formed with the first pivoting portion 142.

Similarly, a second groove 124 is provided on a side of the first side surface 1202 that is close to the fourth side surface 1208, and the second groove 124 extends to a junction of the first side surface 1202 and the fourth side surface 1208. A second fastening slot 125 is provided at a position of the fourth side surface 1208 that is close to the second side surface 1204.

The second fastener 150 includes a second pivoting portion 152 and a second buckling portion 154. The second pivoting portion 152 is arranged in the second groove 124 and pivotally connected to the frame 120. The second buckling portion 154 is connected to the second pivoting portion 152 to be integrally formed with the second pivoting portion 152.

The first side surface 1202 is adapted to abut against the second side surface 1204 of another cooling fan 100. The first fastener 140 is rotated to selectively move the first buckling portion 144 to a folding position to cover the first groove 122 (as shown in FIG. 5) or move to a connecting position to be buckled to the first fastening slot 123 of the another cooling fan 100 (as shown in FIG. 3). Similarly, the second fastener 150 is rotated to selectively move the second buckling portion 154 to a folding position to cover the second groove 124 (as shown in FIG. 5) or move to a connecting position to be buckled to the second fastening slot 125 of the another cooling fan 100 (as shown in FIG. 3).

The cooling fan 100 further includes a first connector 160 and a second connector 170. The first connector 160 is arranged at the first buckling portion 144. The second connector 170 is arranged at a side of the first fastening slot 123. In an embodiment, the first connector 160 and the second connector 170 are connectors having four electrical contacts, to meet an electricity and signal transmission requirement required for operation of the cooling fan 100. Specifically, the second connector 170 is arranged at a side of a fastening position in the first fastening slot 123. The first connector 160 is electrically connected to the second connector 170 through a wire (not shown in the figure) extending along an interior of the frame 120.

In an embodiment, the first connector 160 is arranged at a tail end of the first buckling portion 144, and is located on an inner side surface of the first buckling portion 144 (that is, a surface facing the first groove 122 of the first fastening portion 144 when located at the folding position); and the second connector 170 is arranged on a side of the first fastening slot 123 that is away from the second side surface 1204. The first connector 160 is adapted to be electrically connected to the second connector 170 of the another cooling fan 100. When the first buckling portion 144 moves to the connecting position and is buckled to the first fastening slot 123 of the another cooling fan 100, the first connector 160 on the first buckling portion 144 is electrically connected to the second connector 170 arranged in the first fastening slot 123, so that the two cooling fans 100 are electrically connected.

In an embodiment, the first fastener 140 is made of a buffer material or an elastic material, to alleviate collision between the cooling fans 100. Similarly, the second fastener 150 is also made of a buffer material or an elastic material.

In an embodiment, the cooling fan 100 further includes at least one first buffer cushion 182 (two first buffer cushions 182 are shown in the figure) arranged on the second side surface 1204. The first buffer cushion 182 prevents the frames 120 of adjacent cooling fans 100 from colliding with each other and causing damage. When the first fastener 140 and the second fastener 150 are buckled to another cooling fan 100 for connection, a resilience force provided by the first buffer cushion 182 also helps ensure that the first fastener 140 and the second fastener 150 are firmly buckled to the first fastening slot and the second fastening slot of the another cooling fan 100. Further, in an embodiment, when the cooling fan 100 is connected to another cooling fan 100 through the second side surface 1204, the first buffer cushion 182 extends into the first groove 122 or the second groove 124 of the another cooling fan 100 for positioning.

In an embodiment, the frame 120 includes a front surface 120a, a rear surface 120b, a first locking hole 1212, a second locking hole 1214, a third locking hole 1216, and a fourth locking hole 1218. These locking holes are provided at corners of the frame 120 and extend from the front surface 120a of the frame 120 to the rear surface 120b of the frame 120, to install the cooling fan 100 on a fan base (not shown in the figure) in a locking manner.

An arrangement position of the first locking hole 1212 corresponds to the first groove 122, an arrangement position of the second locking hole 1214 corresponds to the first fastening slot 123, an arrangement position of the third locking hole 1216 corresponds to the second groove 124, and an arrangement position of the fourth locking hole 1218 corresponds to the second fastening slot 125. The first pivoting portion 142 of the first fastener 140 is pivotally connected to the frame 120 through the first locking hole 1212. The second pivoting portion 152 of the second fastener 150 is pivotally connected to the frame 120 through the third locking hole 1216. A locking member (not shown in the figure) arranged in the second locking hole 1214 is configured to buckle the first buckling portion 144 of the another cooling fan 100, and a locking member arranged in the fourth locking hole 1218 is configured to buckle the second buckling portion 154 of the another cooling fan 100.

In an embodiment, the cooling fan 100 further includes at least one second buffer cushions 184 arranged on the front surface 120a of the frame 120. In an embodiment, a number of the second buffer cushions 184 is four, and the four second buffer cushions 184 are arranged at four corners of the front surface 120a of the frame 120. In other embodiments, the second buffer cushion 184 is alternatively arranged on the rear surface 120b of the frame 120, or the second buffer cushion 184 is arranged on the front surface 120a and the rear surface 120b of the frame 120.

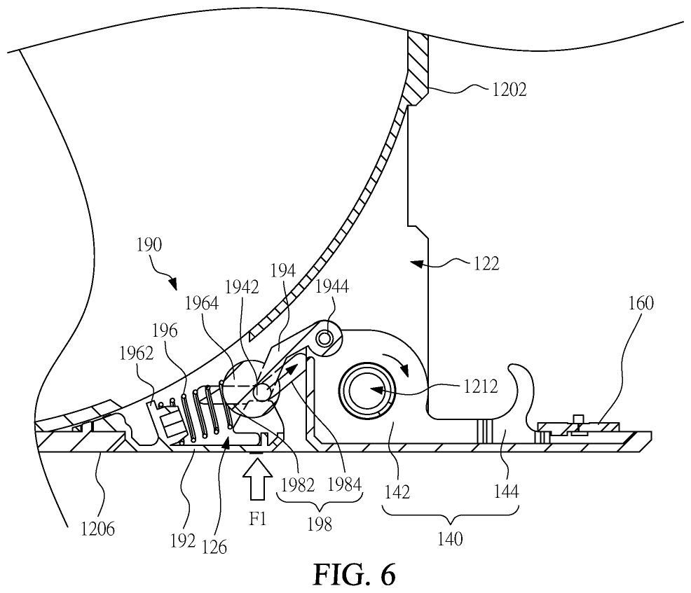

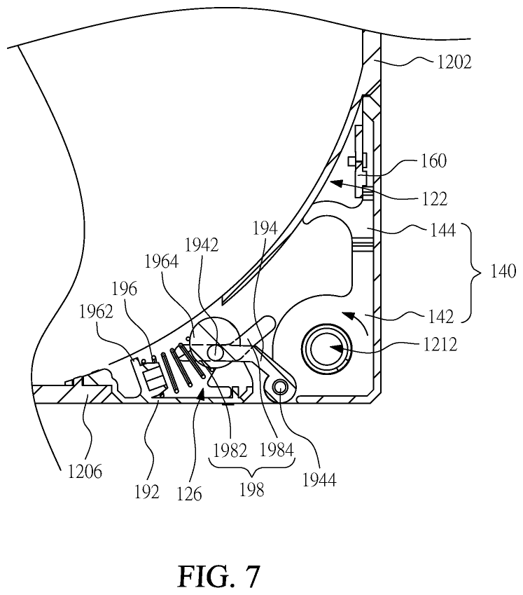

Referring to FIG. 6 and FIG. 7 together, FIG. 6 is a partial schematic perspective view of an internal structure corresponding to a position of a first groove 122 in FIG. 3, and FIG. 7 is a partial schematic perspective view of an internal structure corresponding to a position of a first groove 122 in FIG. 5.

As shown in the figures, a third groove 126 is provided at a position of the third side surface 1206 that is close to the first side surface 1202, the cooling fan 100 further includes a release module 190, and the release module 190 is arranged in the third groove 126.

The release module 190 includes a press member 192, a connecting rod 194, and an elastic member 196. The press member 192 is coupled to the first pivoting portion 142 of the first fastener 140 through the connecting rod 194. The connecting rod 194 includes a first end 1942 and a second end 1944. The first end 1942 is coupled to the elastic member 196 and slidably connected to the frame 120, and the second end 1944 is coupled to the first buckling portion 144. The elastic member 196 includes a third end 1962 and a fourth end 1964. The third end 1962 is fixed to the press member 192, and the fourth end 1964 is coupled to the connecting rod 194. The press member 192 is adapted to drive the first buckling portion 144 to be separated from the first fastening slot 123 of the another cooling fan 100.

Specifically, the first end 1942 of the connecting rod 194 is slidably connected to the frame 120 along a slide rail 198. The slide rail 198 is arranged at the frame 120 and includes a first section 1982 and a second section 1984. The first section 1982 is located on a side of the slide rail 198 that is away from the first side surface 1202, and an extension direction thereof is parallel to a surface direction of the third side surface 1206. The second section 1984 is located on a side of the slide rail 198 that is close to the first side surface 1202, and the second section 1984 extends obliquely toward a direction away from the third side surface 1206.

When the first buckling portion 144 is located at a connecting position, the first buckling portion 144 extends outward along the surface direction of the third side surface 1206, and the connecting rod 194 is slidably connected to the second section 1984. In this case, when the press member 192 moves toward an inner side of the frame 120 under an external force F1, the press member 192 drives the first end 1942 of the connecting rod 194 to move along the second section 1984, to further drive the first buckling portion 144 to rotate toward a direction away from the first groove 122, causing the first buckling portion 144 to be separated from the first fastening slot 123 of the another cooling fan 100. The elastic member 196 provides an elastic restoring force to push the press member 192 to reset. In an embodiment, the elastic member 196 is a spring.

In another aspect, when the first buckling portion 144 is located at a folding position, the first buckling portion 144 extends along a surface direction of the first side surface 1202. In this case, the connecting rod 194 is slidably connected to the first section 1982, to block the press member 192 from moving toward the inner side of the frame 120.

FIG. 6 and FIG. 7 describe positions of the release module 190 arranged on the third side surface 1206 to release a corresponding first fastener 140. As shown in FIG. 1 and FIG. 3, the release module 190 is alternatively arranged at a position of the fourth side surface 1208 that is close to the first side surface 1202 to release a corresponding second fastener 150.

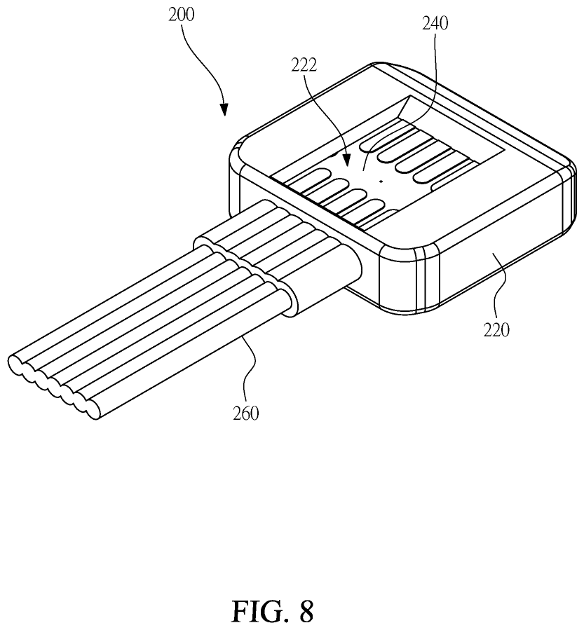

FIG. 8 is a three-dimensional schematic diagram of a transfer element 200 according to an embodiment of the disclosure.

As shown in the figure, the transfer element 200 includes a body 220, a transfer connector 240, and an input connector 260. A groove 222 is provided on a side of the body 220 and is fixed to the second connector 170. The transfer connector 240 is arranged at a bottom of the groove 222 to be electrically connected to the second connector 170. The input connector 260 is arranged on a side of the body 220 to be connected to an external circuit (not shown in the figure) to receive electricity and a control signal.

Referring to the cooling device 10 shown in FIG. 1 and FIG. 2, for the cooling fan 100a therein, the cooling fan 100a is connected to the cooling fan 100b by using the first fastener 140 and the second fastener 150, the first side surface 1202 of the cooling fan 100a abuts against the second side surface 1204 of the cooling fan 100b, the first fastener 140 and the second fastener 150 are buckled to the first fastening slot 123 and the second fastening slot 125 of the cooling fan 100b and located at connecting positions.

The second connector 170 of the cooling fan 100a is connected to the transfer element 200 to obtain the electricity and the control signal and transmit the electricity and the control signal to other cooling fans 100b, 100c, and 100d.

For the cooling fan 100d, the cooling fan 100d does not need to be connected to other cooling fans. The first fastener 140 and the second fastener 150 of the cooling fan 100d cover the first groove 122 and the second groove 124 to be locate at folding positions.

To sum up, the cooling device 10 in the disclosure includes a plurality of cooling fans 100a, 100b, 100c, and 100d. These cooling fans 100a, 100b, 100c, and 100d are connected in rows by fastening and connection between the first fastener 140 and the first fastening slot 123, and between the second fastener 150 and the second fastening slot 125, and utilizes electrical connection of the first connector 160 and the second connector 170 to reduce wires that need to be used, thereby simplifying an installation procedure of the cooling fans. Besides, when the first fastener 140 does not need to be connected to the cooling fans 100a, 100b, 100c, and 100d, the first fastener 140 covers the first groove 122, to prevent a fastening structure of the first fastener 140 and the first connector 160 from being exposed, helping improve the product safety. In addition, the first buffer cushion 182 is arranged on the second side surface 1204 of the frame 120. The first buffer cushion 182 helps prevent butting surfaces of the cooling fans from directly colliding with each other and causing damage.

The foregoing merely describes preferred embodiments of the disclosure, and are not intended to limit the disclosure. Any form of equivalent replacements or modifications to the technical means and technical content disclosed in the disclosure made by a person skilled in the art without departing from the scope of the technical means of the disclosure still fall within the content of the technical means of the disclosure and the protection scope of the disclosure.

What is claimed is:

1. A cooling device, comprising a plurality of cooling fans, wherein each cooling fan comprises:
a frame, comprising a first side surface, a second side surface, and a third side surface, the second side surface being opposite to the first side surface, the third side surface being adjacent to the first side surface and the second side surface, the first side surface comprising a first groove extending to a junction of the first side surface and the third side surface, and a first fastening slot being provided at a position of the third side surface that is close to the second side surface; and
a first fastener, comprising a first pivoting portion and a first buckling portion connected to each other, the first pivoting portion being arranged in the first groove and pivotally connected to the frame, wherein
the first side surface is adapted to abut against the second side surface of another cooling fan to be connected, and the first buckling portion is adapted to selectively cover the first groove or be buckled to the first fastening slot of the another cooling fan to be connected.

2. The cooling device according to claim 1, wherein the cooling fan further comprises a first connector and a second connector, the first connector is arranged at the first buckling portion, the second connector is arranged at a side of the first fastening slot, the first connector is electrically connected to the second connector, and the first connector is adapted to be electrically connected to the second connector of the another cooling fan.

3. The cooling device according to claim 1, wherein the first fastener is made of a buffer material.

4. The cooling device according to claim 1, wherein the cooling fan further comprises a first buffer cushion arranged on the second side surface.

5. The cooling device according to claim 1, wherein the frame comprises a front surface, a rear surface, and a first locking hole, the first locking hole extends from the front surface to the rear surface, and the first pivoting portion is pivotally connected to the frame through the first locking hole.

6. The cooling device according to claim 5, wherein the cooling fan further comprises a second buffer cushion arranged on the front surface.

7. The cooling device according to claim 1, wherein the frame further comprises a fourth side surface opposite to the third side surface and adjacent to the first side surface and the second side surface, the first side surface comprises a second groove extending to a junction of the first side surface and the fourth side surface, a second fastening slot is provided at a position of the fourth side surface that is close to the second side surface, the cooling device further comprises a second fastener having a second pivoting portion and a second buckling portion, the second pivoting portion is arranged in the second groove and pivotally connected to the frame, and the second buckling portion is connected to the second pivoting portion to selectively cover the second groove or be buckled to the second fastening slot of the another cooling fan.

8. The cooling device according to claim 1, wherein a third groove is provided at a position of the third side surface that is close to the first side surface, the cooling fan further comprises a release module, the release module is arranged in the third groove and comprises a press member and a connecting rod, the connecting rod comprises a first end and a second end, the press member is coupled to the first end, the second end is coupled to the first pivoting portion, and the first end is slidably connected to the frame.

9. The cooling device according to claim 8, wherein the release module further comprises an elastic member, the elastic member comprises a third end and a fourth end, the third end is fixed to the press member, and the fourth end is couple to the connecting rod.

10. The cooling device according to claim 9, wherein the elastic member is a spring.

11. The cooling device according to claim 2, further comprising a transfer element to be inserted into the second connector to input electricity and a control signal.
